(19) United States
(12) Patent Application Publication
(10) Pub. No.: US 2006/0285433 A1
(43) Pub. Date: Dec. 21, 2006

(54) Fluidic mixer of serpentine channel incorporated with staggered sudden-expansion and convergent cross sections

(76) Inventors: Jing-Tang Yang, Hsinchu (TW); Kuo-Wei Lin, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/155,635

(22) Filed: Jun. 20, 2005

(51) Int. Cl. B01F 5/02; B81B 1/00

(52) U.S. Cl. 366/341; 366/DIG. 3

(57) ABSTRACT

The present invention discloses a fluidic mixer of serpentine channel incorporated with staggered sudden-expansion and convergent cross sections, which comprises a flat cover and a channel body. The channel body further comprises two L-type mixer inlets, a mixing channel, and two L-type mixer outlets. The configuration of the mixing channel is a single serpentine channel incorporated with staggered sudden-expansion and convergent cross sections, wherein the serpentine structure and the sudden-expansion cross sections induces split flows, which further enable the fluid to stretch and fold so that the contact area within the fluid can be increased. The convergence after sudden expansion in cross section is to prepare the next action of sudden expansion, and such an iterative structure can obviously enhance the mixing effect. The present invention has the following characteristics: planar structure, which enables the measurement and fabrication, particularly the fabrication of micro mixing channel, to be easily undertaken; L-type mixer inlets and outlets, which enables the connection between the mixing channel and external channels to be robust so that the linkage and encapsulation of the micro mixing channel will be advantaged thereby; single-channel design, which enables the flow resistance not to increase owing to the mixing action, and which also enables the working fluid to be able to involve two-phase fluids containing suspension solid particles; low pressure drop; and no bulb residence inside the mixing channel.

### BACKGROUND OF THE INVENTION

1. Field of the Invention

The present invention relates to a fluidic mixer, particularly to a fluidic mixer of serpentine channel incorporated with staggered sudden-expansion and convergent cross sections, which can overcome the problems usually occurring in the fluid mixing performed in micro channel, such as high flow resistance, bulb residence, and inferior mixing effect in low flow-rate mixing.

2. Description of the Related Art

Mixing in the fluid system is an omnipresent phenomenon and can be seen everywhere, from the heat transference, mass transportation and mass exchange in a system as large as the atmosphere or an ocean current to the reaction and material transportation in a micro system such as a biologic cell. In chemical analysis, chemical synthesis, or other technology, mixing is a universal process. Thus, the control of mixing is critical.

The design of the fluidic mixer needs to meet the demands: the mixer design be simple; the mixer be economically fabricated and consume economical energy; the mixing be performed in limited space and completed in limited time. The fluidic mixer can be categorized into active type and passive type according to the energy for performing mixing. In the active-type mixer, in addition to the force driving the fluid to move, another external force is also applied to the fluid in order to enhance the mixing effect. The action of the external force can be: disturbing the fluid from the surface, deforming or moving the structure, or even pre-injecting a second-phase material to internally agitate the fluid. However, the passive-type mixer directly adopts the force, which drives the fluid to move, to perform the mixing action.

Referring to FIG. 1 showing a prior art U.S. Pat. No. 2,511,291 invented in 1950, it is a mixing apparatus of hot and cold water, wherein respectively from a cold water inlet 01 and a hot water inlet 02, hot and cold water enters a mixing chamber 03 where the structure splits the water flow into diffluent flows 04, 05; then, the diffluent flows 04, 05 is combined into a confluent flow in a confluent chamber 06. Those several times of diffluent and confluent actions will generate an intensive convective agitation, which can increase the contact area between the flows, so that the objective of mixing energy and mass can be achieved. This prior art has superior mixing effect in an appropriate dimension; however, the channel structure thereof seems somewhat complicated for the fluid mixing performed at low flow rate and in small-dimension tube.

Referring to FIG. 2, a prior art U.S. Pat. No. 005,813,762A, which is used in mixing of low viscosity fluid, has slotted baffle boards 07,08, and the angle contained between the slot and the straight pipe ranges from 20 to 60 degrees, with 35 to 45 degrees preferred. Such a kind of mixer is characterized in that the mixing effect is determined by the spacing between the baffle boards, the angles and sizes of the slots. It advantages in very low flow resistance; however, baffle boards needs to be installed inside a pipe, which increases the fabrication complexity.

Referring to FIG. 3, in a prior art RU 2189852 C1, when passing through a nozzle 09, the fluid will be speeded up to form turbulence; when entering into a sudden expansion portion, the fluid will has a variety of eddies, which can promote the effect of convective agitation; when the fluid enters into a necking portion 10, a confluence occurs. This prior art has a better effect in a high flow rate occasion; however, there is almost no mixing effect when the flow rate is low. Accordingly, this prior art is adapted for the mass-transportation occasion, such as the petrochemical industry.

In 2001, Yang et al. proposed an active-type mixer, wherein a channel is fabricated with a photolithographic process, and then a piezoelectric film is applied to a silicon film to create a 60 Hz vibration with a voltage of 50V in order to agitate the fluid inside a mixing chamber. A fluorescent microscope is used to measure the intensity of the reflected light of water-soluble fluorescent agent, and a laser Doppler interferometer is used to detect the amplitude of the film's vibration. The ultrasonic vibration utilized in this prior art has the following advantages: turbulence can be created instantly; and different frequency, amplitude, and interval of ultrasonic agitation can be selected to meet the demand of different mixing extent of the same fluid. However, this prior art has the following disadvantages: the ultrasonic vibration in some frequency range is apt to induce cavitations, which will generates bulbs; the film's vibration will generate Joule heat, which will raise the temperature, and change the physical and chemical properties of material; the fabrication cost is higher than that of the present invention; the design thereof is pretty complicated; and the mixing effect is hard to control.

In 1993, Miyake et al. proposed a passive-type micro mixer with a photolithographic process. As the Reynolds number of fluid is usually very low in microstructures, their design is focused on how to increase the contact area between two phases of liquids. Before entering into the other liquid to be mixed, a second phase liquid is partitioned by a porous board to directly enhance the mixing effect via diffusion. The porous-type mixer has the advantage that mixing extent is easily controlled. Higher pore density for partition makes mixing of diffusion type better. In comparison with the present invention, this porous-type mixer has more fluidic interfaces, which consumes more energy for higher flow resistance.

In 2000, Ismagilov et al. proposed a mixer, wherein a calcium chloride solution and a fluid having fluorescent agent are joined to enter into a single straight channel, i.e. a T-shape channel, and a conjugate-focus fluorescent microscope is used to observe the fluorescent light emitted by the mixed fluid. It is observed: wall viscosity slows down the flow of fluid; transverse diffusion thus has more time to undertake; and in comparison with the central portion, the perimeter has better mixing effect. However, in comparison with the present invention, the mixing effect of this prior art is not perfect yet.

In 2002, Stroock et al. proposed a crossed fish-bond bottom channel, which utilizes stretching and iteratively magnified disturbance of asymmetric interfaces to create transverse-oscillation eddies in order to effectively stretch and fold the interfaces between two fluids, which can generate transverse stretching and folding and realize the passive mixing within a micro channel and with the Reynolds number less than 0.01. In comparison with the present invention, this prior art has a superior mixing effect; however, the three-dimensional fabrication thereof is pretty complicated and expensive.

In 1996, Schwesinger et al. utilized the separation, combination, and pressure drop of fluid to design a series of forked mixing elements, which can successfully achieve agitating the fluid, stretching and distorting the interfacial layers of the fluid and can obtain an effective mixing. However, in comparison with the present invention, the three-dimensional fabrication thereof is complicated and expensive.

In 2000, Liu et al. designed a zag-channel mixer, which utilizes the chaotic flows induced by the zagging of the channel to enhance mixing effect. Under the conditions of identical path length and identical zags' number, the mixing effects of the three-dimensional serpentine, the planar serpentine, and the straight mixer are compared. In comparison with the present invention, the planar serpentine channel has worse mixing effect; the three-dimensional serpentine channel has better mixing effect; however, the fabrication of the three-dimensional serpentine channel is pretty complicated and expensive.

### SUMMARY OF THE INVENTION

The primary objective of the present invention is to provide a fluidic mixer of serpentine channel incorporated with staggered sudden-expansion and convergent cross sections, which not only can obviously enhance the mixing effect but also can be applied to the fluid mixings in various fields and various dimensions.

Another objective of the present invention is to provide a fluidic mixer of serpentine channel incorporated with staggered sudden-expansion and convergent cross sections, wherein not only the mixer can be economically fabricated, but also the mixer itself is endurable.

Yet another objective of the present invention is to provide a fluidic mixer of serpentine channel incorporated with staggered sudden-expansion and convergent cross sections, which can overcome the problems usually occurring in the fluid mixing performed in a micro channel.

Further another objective of the present invention is to provide a fluidic mixer of serpentine channel incorporated with staggered sudden-expansion and convergent cross sections, wherein the working fluid can involve two-phase fluids containing suspension solid particles.

Still another objective of the present invention is to provide a fluidic mixer of serpentine channel incorporated with staggered sudden-expansion and convergent cross sections, wherein the connection between the mixing channel and external channels is robust so that the linkage and encapsulation of the micro mixing channel can be easily accomplished.

Still further objective of the present invention is to provide a fluidic mixer of serpentine channel incorporated with staggered sudden-expansion and convergent cross sections, wherein the contact area between the streams within the fluid is increased.

Still further objective of the present invention is to provide a fluidic mixer of serpentine channel incorporated with staggered sudden-expansion and convergent cross sections, wherein the mixing process can be conveniently detected.

To achieve the aforementioned objectives, the fluidic mixer of serpentine channel incorporated with staggered sudden-expansion and convergent cross sections of the present invention comprises a transparent flat cover and a planar-fabrication channel body. The channel body further comprises two L-type mixer inlets, a mixing channel, and two L-type mixer outlets. The configuration of the mixing channel is a single serpentine channel incorporated with staggered sudden expansion and convergent cross sections, wherein the serpentine structure and the sudden-expansion cross sections can induce a flow splitting, which further enables the fluid to stretch and fold so that the contact area within the fluid can be increased. The convergence after sudden expansion in cross section is to prepare the next action of sudden expansion, and such an iterative structure can obviously enhance the mixing effect. The single-channel design can enable the flow resistance not to increase owing to the mixing action and can also enable the working fluid to be able to involve two-phase fluids containing suspension solid particles; the mixing channel of the present invention can also be free from bulb residence. The L-type mixer inlets and outlets can enable the connection between the mixing channel and external channels to be robust so that the linkage and encapsulation of the micro channel will be advantaged thereby. The planar design of the mixing channel and the transparent flat cover can enable the mixing process to be detected via a non-destructive optical method. The planar design of the mixing channel can also enable the mixer to be easily fabricated.

To enable the objectives, technical contents, characteristics, and accomplishments of the present invention to be more easily understood, the embodiments of the present invention are to be described below in detail in cooperation with the attached drawings.

### BRIEF DESCRIPTION OF THE DRAWINGS

FIG. 1 shows a prior art U.S. Pat. No. 2,511,291.

FIG. 2 shows a prior art U.S. Pat. No. 005,813,762A.

FIG. 3 shows a prior art RU 2189852 C1.

FIG. 4 is a schematic diagram of the fluidic mixer of serpentine channel incorporated with staggered sudden-expansion and convergent cross sections according to one embodiment of the present invention.

FIG. 5 shows the photograph of a micrometric fluidic mixer according to one embodiment of the present invention.

FIG. 6 shows the photograph of the homogeneously mixed fluid in the micrometric fluidic mixer according to one embodiment of the present invention.

FIG. 7 is a schematic diagram of a conventional serpentine-type mixer.

FIG. 8 shows the images of practical mixing process of a straight-tube-type mixer at low flow rate.

FIG. 9 shows the images of practical mixing process of a straight-tube-type mixer at high flow rate.

FIG. 10 shows the images of practical mixing process of a serpentine-type mixer at low flow rate.

FIG. 11 shows the images of practical mixing process of a serpentine-type mixer at high flow rate.

FIG. 12 shows the images of practical mixing process the fluidic mixer of the present invention at low flow rate.

FIG. 13 shows the images of practical mixing process the fluidic mixer of the present invention at high flow rate.

FIG. 14A shows the diagram of the simulation results of a straight-tube-type mixer at a flow rate of 0.4 ml/min.

FIG. 14B shows the diagram of the simulation results of a serpentine-type mixer at a flow rate of 0.4 ml/min.

FIG. 14C shows the diagram of the simulation results of the fluidic mixer of serpentine channel incorporated with staggered sudden-expansion and convergent cross sections of the present invention at a flow rate of 0.4 ml/min.

FIG. 15 shows the diagram of the mixing extents of the fluids with respect to the positions in the channels of the fluidic mixer of serpentine channel incorporated with staggered sudden-expansion and convergent cross sections of the present invention, a serpentine-type mixer, and a straight-tube-type mixer at a flow rate of 0.4 ml/mm.

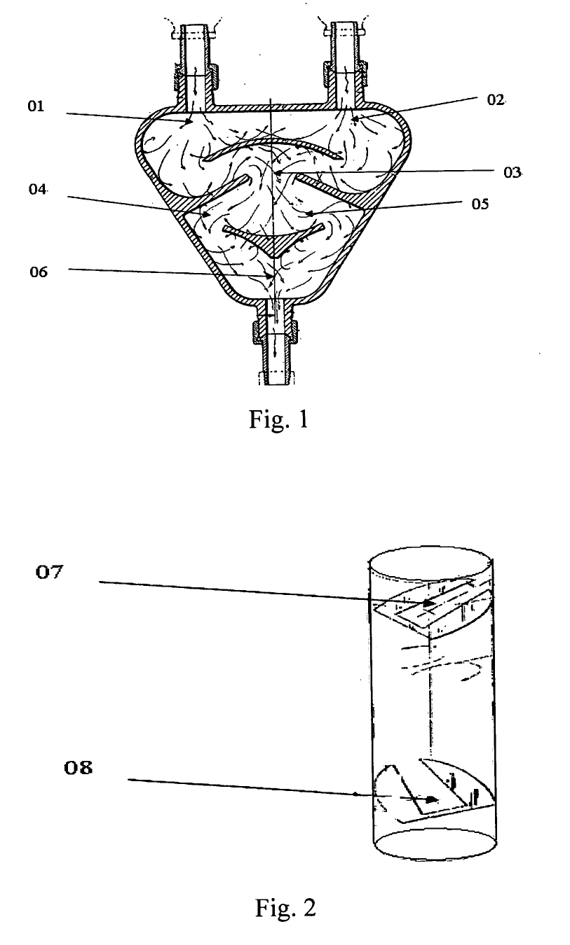

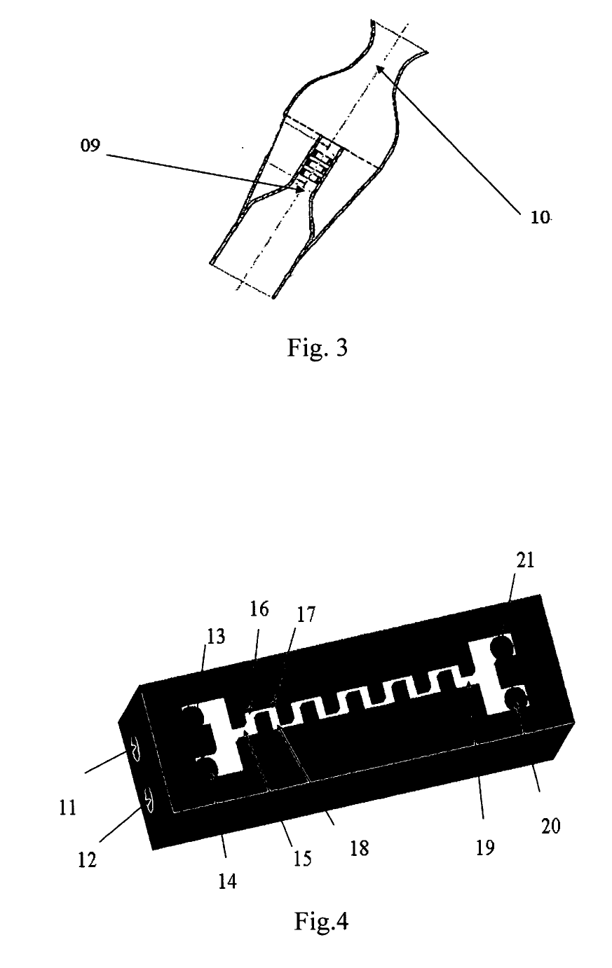

### DETAILED DESCRIPTION OF THE INVENTION

The fluidic mixer of the present invention is a passive one. The active forces of passive fluid mixing include inertia force and interfacial force. When the characteristic dimension is larger, the inertia force will dominate; however, when the characteristic dimension is small, the interfacial force should not be neglected. The factors influencing mixing effect include: flow rate, density, viscosity, diffusive coefficient, chemical properties, and interfacial force. The mechanism of convective mixing is the iterative stretching and folding of fluid interfaces. The present invention is to design appropriate geometrical shape and dimension to exploit the aforementioned active forces in order to create the aforementioned mechanism.

The fluidic mixer of serpentine channel incorporated with staggered sudden-expansion and convergent cross sections of the present invention comprises a flat cover and a channel body. Referring to FIG. 4 a schematic diagram of the fluidic mixer of serpentine channel incorporated with staggered sudden-expansion and convergent cross sections according to one embodiment of the present invention, the channel body further comprises two L-type mixer inlets 11,12, a mixing channel, and two L-type mixer outlets; the fluids to be mixed enter into the fluidic mixer via two L-type mixer inlets 11,12 respectively, and after passing through L-type zags, the fluids enter into the mixing channel via channel inlets 13,14; the design of the L-type mixer inlets 11,12 is to enable the fluidic mixer of the present invention to be connected to the external pipes with a diameter larger than that of the mixing channel so that the problem resulting from the connection between the tiny mixing channel and the external pipe can be avoided; the fluids to be mixed is joined and mixed in the channel entrance 15; after the first zag 16, the mixing channel is shrunk to prepare for the second zag 17 and the coming sudden expansion; in the second zag 17, the sudden asymmetric change of transverse pressure and the non-slip between the wall and the fluid induces the streamline to be unstable and distorted, and the fluid has a longitudinal deformation, and the gradient of transverse speed increases, which will advantage the transverse diffusion in the fluid being mixed; further, under the asymmetric boundary condition, such as tremendous direction change, the force driving the fluid to flow cannot overcome the reverse pressure resulting from the shape change of the mixing channel; when the fluid has a high flow speed, the fluid flow can be retarded or even reversed to form a backflow region, which will advantage the inflecting of the fluid; after the third zag 18, the mixing channel is again shrunk to prepare for the succeeding zag and the coming sudden expansion; after the iterative shrinks and expansions of the mixing channel, which repeat the same action, the fluid mixing is completed, and the fluid exits from channel exit 19 and toward channel outlets 20,21 where the fluid is split to enter into the channel outlets 20,21 separately; wherein
the first L-type mixer inlet 11 has a diameter of 2.5×10⁻³ m;
the second L-type mixer inlet 12 has a diameter of 2.5×10⁻³ m;
the first channel inlet 13 has a diameter of 2.5×10⁻³ m;
the second channel inlet 14 has a diameter of 2.5×10⁻³ m;
the channel entrance 15 has a width of 1×10⁻³ m;
the first zag 16 has a following shrink channel with a width of 5×10⁻⁴ m;
the second zag 17 has a following expansive channel with a width of 1×10⁻³ m;
the third zag 18 has a following shrink channel with a width of 5×10⁻⁴ m;
the channel exit 19 has a width of 1×10⁻³ m;
the first channel outlet 20 has a width of 2.5×10⁻³ m; and
the second channel outlet 21 has a width of 2.5×10⁻³ m.

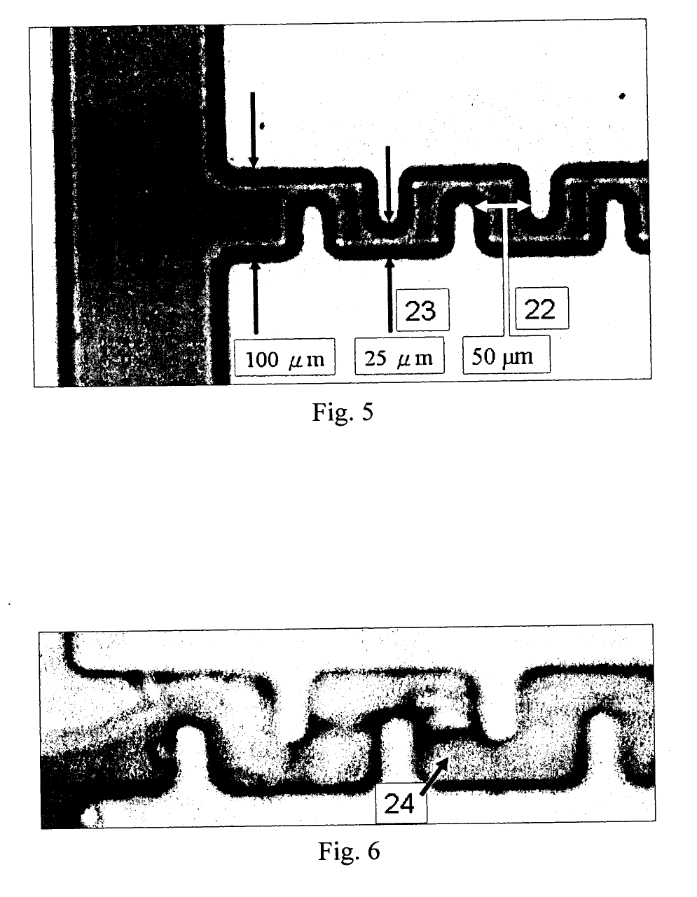

FIG. 5 shows the photograph of a micrometric fluidic mixer according to one embodiment of the present invention, which is made of a polymeric material and jointed via a thermal fusion or activating surface with plasma, wherein the width of the sudden expansion region 22 is 50 μm, and the width of the shrink region 23 is 25 μm. The homogeneously mixed fluid is shown in the region designated by 24 in FIG. 6.

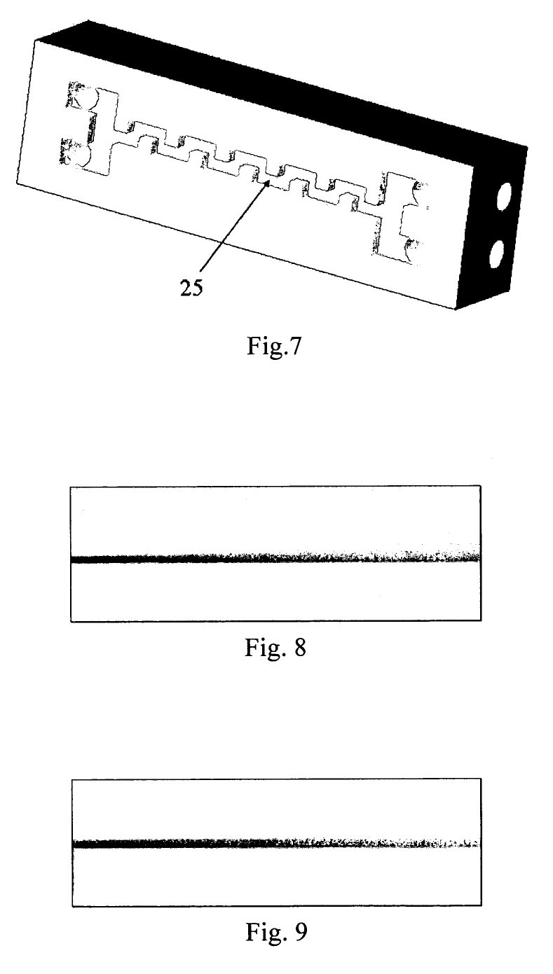

The concentration variation resulting from mixing will be used in practical measurement and numerical simulation of mixing effect in order to compare the present invention with a straight-tube-type mixer and a serpentine-type mixer, wherein the channel of the serpentine-type mixer has a width 25 of 1×10⁻³ m, as shown in FIG. 7.

As there is a direct correlation between the concentration and the grayscale of the fluid, the grayscale is adopted and processed in this experiment. Deionized water is used as the working fluid; a food dye cochineal red A and an edible tackifier (cellulose sodium oxalate) is added to the deionized water to form a red fluid, wherein the mass concentration of the dye and the tackifier are separately 0.1968% w/w and 0.4106% w/w; the edible tackifier (cellulose sodium oxalate) is also added to the deionized water to form a transparent fluid, wherein the mass concentration of the tackifier are 0.4614% w/w. The grayscales of two confluent fluids are measured to indicate the mixing extent. Both of the red fluid and the transparent fluid have the same viscosity of 4.78×10⁻³ N·s/m². The working fluid is driven with an injection-type pump (KDS220, KD Scientific, USA). The images of fluid mixing process are taken with a digital camera (Olympus-C730, Japan). The volumetric flow rates of the test fluid are separately 0.2, 0.4, 0.8, 1.6, 3.2 and 6.4 ml/min.

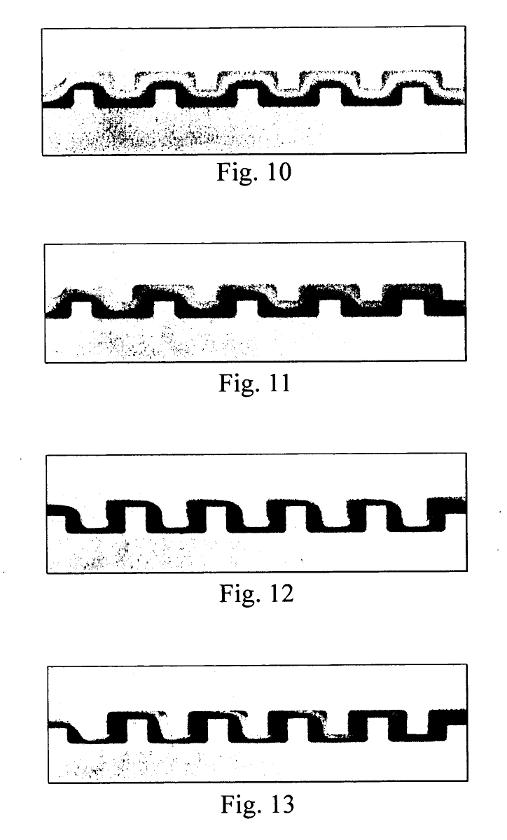

FIG. 8 to FIG.13 separately shows the images of practical mixing process of a straight-tube-type mixer, a serpentine-type mixer and the present invention at the flow rates of 0.2 and 6.4 ml/min. The experimental results show: at low flow rate, the mixing effects of those three mixers are similar; however, at high flow rate, the mixing effect of the straight-tube-type mixer becomes worse, and the mixing effects of the serpentine-type mixer and the fluidic mixer of serpentine channel incorporated with staggered sudden-expansion and convergent cross sections becomes well; in comparison with the serpentine-type mixer, the fluidic mixer of serpentine channel incorporated with staggered sudden-expansion and convergent cross sections can even effectively enhance the mixing action at low flow rate, and the enhancing effect is still more obvious at high flow rate. Accordingly, in comparison with the straight-tube-type mixer and the serpentine-type mixer, the present invention not only has still better mixing effect but also can be free from bulb residence and flow retarding, which can further save much time and space.

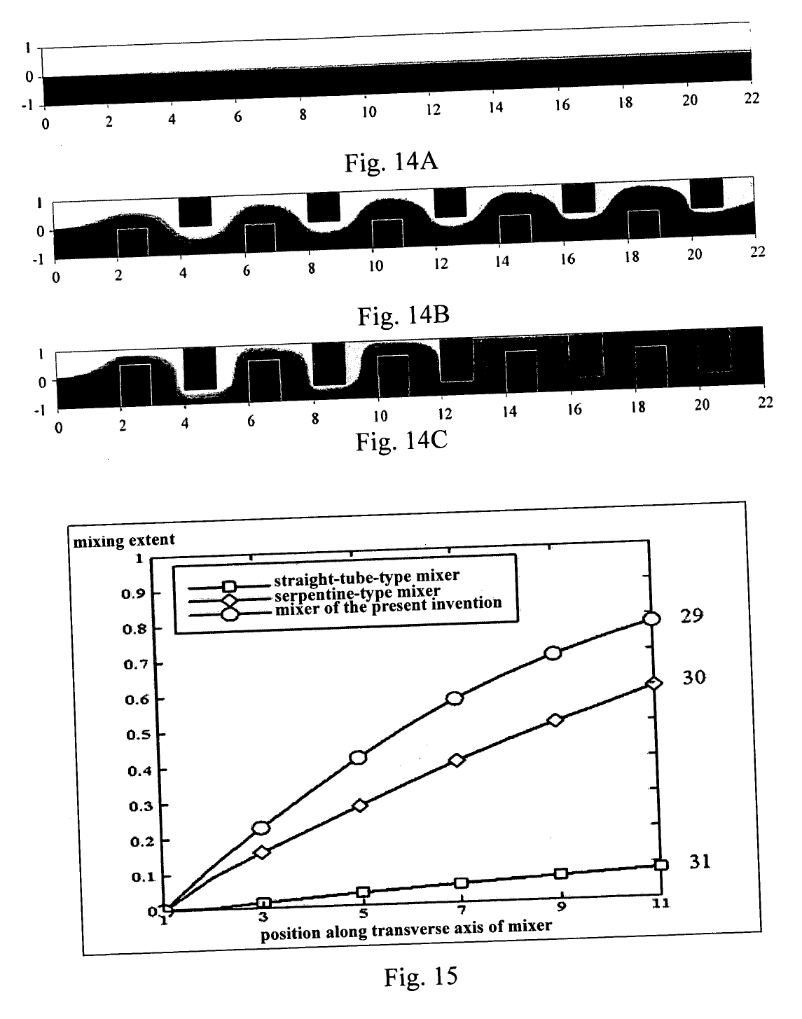

FIG. 14A, 14B, and 14C show respectively the simulation results of a straight-tube-type mixer, a serpentine-type mixer and the fluidic mixer of serpentine channel incorporated with staggered sudden-expansion and convergent cross sections of the present invention, wherein the simulations are performed via CFD-RC™. The simulation results show that the fluidic mixer of serpentine channel incorporated with staggered sudden-expansion and convergent cross sections of the present invention has the best mixing effect among those three mixers. This simulation is performed on the assumptions: the test fluids are Newtonian and incompressible fluids; the viscosities and diffusive coefficients of the fluids are constant; the gravity is neglected; and no chemical reaction occurs in the fluids. System equations include: continuous equation, momentum equation and concentration equation. The boundary conditions include: the channel wall is a non-slip one; the fluids at channel entrance are uniform flows; the fluids entering into both channel inlets are respectively a white water and a black water; and both the fluids have the same flow rate of 0.4 ml/min. In the estimation of the mixing extent, the concentration change is used to calculate the standard deviation, and then a normalization processing is performed so that the completion of mixing is defined to be 1, and the completely non-miscible state is defined to be 0.

FIG. 15 shows the simulated mixing extents of the fluids with respect to the positions in the channels of three aforementioned mixers at a flow rate of 0.4 ml/mm, wherein 29, 30 and 31 are respectively the simulated mixing extents of the fluidic mixer of serpentine channel incorporated with staggered sudden-expansion and convergent cross sections of the present invention, the serpentine-type mixer, and the straight-tube-type mixer with respect to the positions in the X-axis representing the distance downstream from the channel entrance, and wherein the first analysis point is at the position of 2.5×10⁻³ m in the X-axis, and the following analysis points are separated in a spacing of 2×10⁻³ m.

The embodiments described above are only to clarify the technical thoughts and characteristics of the present invention and to enable the persons skilled in the art to understand, make, and use the present invention, but not intended to limit the scope of the present invention. Any equivalent modification and variation according to the spirit of the present invention is to be included within the scope of the present invention.

What is claimed is:

1. A fluidic mixer, comprising:
two inlet channels;
a mixing channel, having a serpentine configuration incorporated with staggered sudden-expansion and convergent cross sections, and further comprising an entrance and an exit, wherein said entrance of said mixing channel interconnects said two inlet channels, and two fluids enter into said fluidic mixer via said two inlet channels, and then said two fluids are joined to enter into said mixing channel; and
two outlet channels, interconnecting said exit of said mixing channel, wherein the fluid having flowed through said mixing channel is split to exit via said two outlet channels separately.

2. The fluidic mixer according to claim 1, wherein said inlet channel is a L-type zag.

3. The fluidic mixer according to claim 1, wherein the diameter of said inlet channel ranges from 1×10⁻⁶ m to 1×10⁻² m.

4. The fluidic mixer according to claim 1, wherein the cross section of said mixing channel varies with respect to positions along the central line of said mixing channel.

5. The fluidic mixer according to claim 1, wherein the maximum cross-sectional area of said mixing channel ranges from 3×10⁻¹² m² to 9×10⁻⁵ m².

6. The fluidic mixer according to claim 1, wherein the minimum cross-sectional area of said mixing channel ranges from 2.5×10⁻¹² m² to 1×10⁻⁴ m².

7. The fluidic mixer according to claim 1, wherein the ratio of the maximum to the minimum cross-sectional area of said mixing channel ranges from 1.5 to 10.

8. The fluidic mixer according to claim 1, wherein the total length of said mixing channel ranges from 5×10⁻⁶ to 3×10⁻² m.

9. The fluidic mixer according to claim 1, wherein said mixing channel zags at least twice.

10. The fluidic mixer according to claim 1, whose application field includes mass mixing, momentum mixing, and/or energy mixing.

11. The fluidic mixer according to claim 11, wherein said energy mixing further comprises heat exchange and/or heat dissipation.
